(19) United States
(12) Patent Application Publication
(10) Pub. No.: US 2024/0014088 A1
(43) Pub. Date: Jan. 11, 2024

(54) POWER SEMICONDUCTOR DEVICE

(71) Applicant: Hitachi Power Semiconductor Device, Ltd., Hitachi-shi, Ibaraki (JP)

(72) Inventors: Junpei Kusukawa, Tokyo (JP); Eiichi Ide, Tokyo (JP); Akira Mima, Tokyo (JP)

(73) Assignee: Hitachi Power Semiconductor Device, Ltd., Hitachi-shi, Ibaraki (JP)

(21) Appl. No.: 18/253,611

(22) PCT Filed: Nov. 25, 2021
(86) PCT No.: PCT/JP2021/043161

§ 371 Date: May 19, 2023

(30) Foreign Application Priority Data
Feb. 3, 2021 (JP) 2021-015673

(51) Int. Cl. H01L 23/31; H01L 23/00; H01L 23/60; H01L 25/07

(52) U.S. Cl. CPC H01L 23/3135; H01L 24/48; H01L 23/60; H01L 24/32; H01L 24/73; H01L 25/072; H01L 2924/181; H01L 2224/48137; H01L 2224/48225; H01L 2224/32225; H01L 2224/73265

(57) ABSTRACT

Provided is a compact and highly reliable power semiconductor device that prevents partial discharge originating from voids generated by the entering of water vapor from the exterior of the semiconductor device through a sealing resin or voids generated between a main terminal and the sealing resin when the main terminal is heated. The power semiconductor device comprises an insulating substrate, a semiconductor element provided on a front surface of the insulating substrate, and a gel-like first insulation material for sealing the semiconductor element. The power semiconductor device further includes a plate-shaped terminal for electrically connecting the semiconductor element and an external equipment, and an entire portion of the plate-shaped terminal surrounded by the first insulating material is covered with a second insulating material having a hardness greater than that of the first insulating material.

### TECHNICAL FIELD

The present invention relates to a power semiconductor device.

### BACKGROUND ART

In recent years, environmental and resource problems on a global scale have been highlighted, and for effective use of resources, promotion of energy saving, and suppression of global warming gas emission, a highly efficient power conversion device represented by an inverter device using switching of a power semiconductor element has attracted attention. Such power conversion devices are widely applied and developed for home electric appliances such as refrigerators and air conditioners as well as industrial machines, and hybrid electric vehicles (HEV), electric vehicles (EV), railway, electric power, social infrastructure-related equipment, or the like.

The power conversion device includes many components such as a power semiconductor device (power module) incorporating power semiconductor elements such as an insulated gate bipolar transistor (IGBT), a bus bar, a capacitor, an inductor, various sensors, and a control circuit. A compact and highly reliable power conversion device is required for space reduction and safety of an installation area. For this purpose, size reduction and high reliability of the power semiconductor device, which is a main component of the power conversion device, are important.

Currently, IGBTs, diodes, and the like mainly made of Si are used for the power semiconductor elements of the power semiconductor device. As described above, the power semiconductor device has been reduced in size and increased in capacity, and accordingly, a stable operation at a high temperature is required. In addition, the power semiconductor element is also required to have “high withstand voltage”, “low on-resistance”, and “high-speed switching” characteristics, and SiC having a dielectric breakdown field strength of 10 times that of Si and a band gap of 3 times that of Si starts to be applied as next-generation power semiconductor elements and is expected to become widespread. In the next-generation power semiconductor elements, the elements can be used at a temperature higher than that of the Si device, and thus the power semiconductor device is required to have high reliability in high temperature operation.

For example, PTL 1 discloses a semiconductor device intended to achieve high reliability in high temperature operation. PTL 1 discloses a semiconductor device including a semiconductor element substrate 4 in which a front-surface electrode pattern 2 is formed on a front surface of an insulating substrate 1 and a back-surface electrode pattern 3 is formed on a back surface of the insulating substrate 1, semiconductor elements 5 and 6 provided on a front surface of the front-surface electrode pattern 2 via a bonding material 7, a first sealing resin 12 covering the semiconductor elements 5 and 6 and the front-surface electrode pattern 2, and a second sealing resin 120 covering at least a portion, which is not formed with the front-surface electrode pattern 2 or the back-surface electrode pattern 3, of the front surface of the insulating substrate 1 and the first sealing resin 12. In PTL 1, the elastic modulus of the second sealing resin 120 is smaller than the elastic modulus of the first sealing resin 12, and a step is provided such that the central portion of the first sealing resin 12 corresponding to the semiconductor elements 5 and 6 is thicker than the peripheral portion.

According to the configuration of PTL 1, since the portion where the insulating substrate 1 is exposed is covered with the second sealing resin 120 having a lower elastic modulus than the first sealing resin 12, when a heat cycle occurs, the stress generated by a difference in expansion coefficient between the first sealing resin 12 and the insulating substrate 1 is alleviated in the portion of the second sealing resin 120 having a lower elastic modulus than the first sealing resin 12, that is, softer than the first sealing resin, so that the first sealing resin 12 is hardly peeled or cracked, and a highly reliable semiconductor device can be obtained. In addition, due to the step, the force pressing the semiconductor elements 5 and 6 is strong, so that peeling of the bonding material 7 can be suppressed, and the shearing stress generated in the first sealing resin 12 at the point E of the end portion of the first sealing resin 12 at the portion where the first sealing resin 12 and the front-surface electrode pattern 2 are in contact with each other is alleviated, so that peeling hardly occurs.

In PTL 2, a semiconductor device 100 including a semiconductor element substrate 3 in which semiconductor elements 1a and 1b are fixed on a front surface electrode 3b, a plurality of main terminals 5a and 5b respectively bonded to upper surfaces of the semiconductor elements 1a and 1b and the front surface electrode 3b, a heat dissipation plate 10 in which a plurality of internal modules including a first sealing resin 9 that seals an inside of a first case 4 provided in a peripheral portion of the front surface electrode 3b to cover the semiconductor elements 1a and 1b and the semiconductor element substrate 3 are arranged, and a second sealing resin 13 that seals an inside of a second case 12 provided in a peripheral portion of the heat dissipation plate 10 to cover the first sealing resin 9, the first case 4, and the semiconductor element substrate 3 is disclosed as a highly reliable semiconductor device in which peeling and cracking are suppressed with a simple structure.

Then, the semiconductor device 100 is disclosed in which the front surface electrode 3b in the first case 4 covers the entire insulating substrate 3a, the front surface electrode 3b and a back surface electrode 3c are formed symmetrically with respect to the insulating substrate 3a, the plurality of main terminals 5a and 5b are exposed to the outside of the second sealing resin 13, and the elastic modulus of the second sealing resin 13 is smaller than the elastic modulus of the first sealing resin 9. According to PTL 2, since a portion of the semiconductor element substrate 3 where the insulating substrate 3a and the sealing resin are in contact with each other serves as the second sealing resin 13 having a small elastic modulus as a sealing resin, stress is reduced, and peeling at this portion is suppressed.

### CITATION LIST

### Patent Literature

PTL 1: JP 2013-16684 A
PTL 2: JP 2015-130457 A

### SUMMARY OF INVENTION

### Technical Problem

PTL 1 and PTL 2 described above have a configuration in which a semiconductor element is covered with a relatively hard first sealing resin (epoxy-based resin or the like), and the periphery thereof is covered with a second sealing resin (silicone-based or urethane-based) softer than the first sealing resin. According to such a configuration, since the resin in contact with the insulating substrate serves as the second sealing resin softer than the first sealing resin, the stress of the insulating substrate is alleviated, and it is possible to suppress cracking of the sealing resin and peeling off from the substrate even when the semiconductor element is subjected to a heat cycle.

On the other hand, in the power semiconductor device, there is a risk that when the main terminal is heated by the high-temperature operation, voids (bubbles) existing between the main terminal and the sealing resin or voids occurring when water vapor that has entered from the outside of the semiconductor device through the sealing resin is heated and vaporized become starting points of partial discharge, and the dielectric breakdown of the semiconductor device occurs. In the techniques of PTL 1 and PTL 2 described above, no consideration has been given to preventing partial discharge due to the voids occurring when the main terminal is heated, and further improvement has been required in this respect.

In view of the above circumstances, an object of the present invention is to provide a compact and highly reliable power semiconductor device that prevents partial discharge starting, when a main terminal is heated, from a void occurring between the main terminal and a sealing resin or a void occurring by water vapor having entered from an outside of the semiconductor device through the sealing resin.

### Solution to Problem

In one aspect of the present invention for achieving the above object, a power semiconductor device which includes an insulating substrate, a semiconductor element provided on a front surface of the insulating substrate, and a gel-like first insulating material that seals the semiconductor element, the device includes: a plate-shaped terminal for electrically connecting the semiconductor element and external equipment. An entire portion of the plate-shaped terminal surrounded by the first insulating material is covered with a second insulating material having a higher hardness than the first insulating material.

### Advantageous Effects of Invention

According to the present invention, it is possible to provide the compact and highly reliable power semiconductor device that prevents partial discharge starting from the void occurring between the main terminal and the sealing resin or the void occurring by the water vapor having entered from the outside of the semiconductor device through the sealing resin.

### BRIEF DESCRIPTION OF DRAWINGS

FIG. 1 is a schematic cross-sectional view illustrating a first embodiment of a power semiconductor device of the present invention.

FIG. 2 is a schematic cross-sectional view illustrating a second embodiment of the power semiconductor device of the present invention.

FIG. 3 is a schematic cross-sectional view of a power semiconductor device of a first comparative example (conventional first example).

FIG. 4 is an enlarged view of a main terminal and a periphery thereof in FIG. 3.

FIG. 5 is a schematic cross-sectional view of a power semiconductor device of a second comparative example (conventional second example).

FIG. 6 is a diagram illustrating a current leak generated between main terminals in the power semiconductor device of FIG. 5.

FIG. 7 is an enlarged cross-sectional view of a periphery of a bonded portion with a circuit electrode of FIG. 3.

FIG. 8 is a schematic cross-sectional view illustrating a third embodiment of the power semiconductor device of the present invention.

### DESCRIPTION OF EMBODIMENTS

### First Embodiment

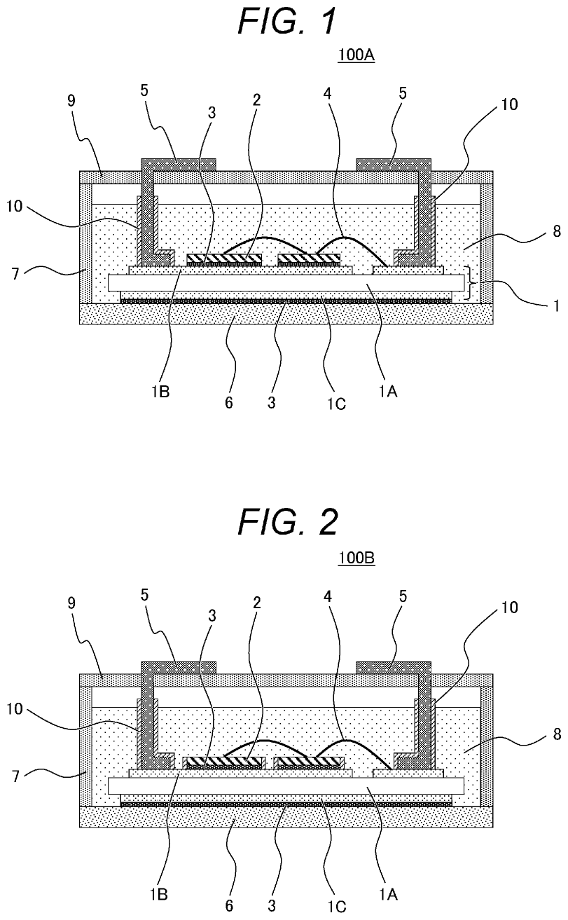

FIG. 1 is a schematic cross-sectional view illustrating a first embodiment of a power semiconductor device of the present invention. A power semiconductor device 100A illustrated in FIG. 1 includes an insulating circuit substrate 1, a power semiconductor element (also simply referred to as a “semiconductor element”) 2, and a gel-like first insulating material 8 that seals the insulating circuit substrate 1 and the power semiconductor element 2. The insulating circuit substrate 1 and the power semiconductor element 2 are housed in a resin case 7, and the inside of the resin case 7 is filled with the first insulating material 8 and sealed by being sealed with a resin case lid 9.

The insulating circuit substrate 1 includes an insulating substrate 1A. A circuit electrode 1B is bonded to one surface of the insulating substrate 1A, and a back surface electrode 1C is bonded to the other surface of the insulating substrate 1A via a brazing material (not illustrated).

The back surface electrode 1C is fixed to a heat dissipation base 6 by a bonding material 3 such as solder. The power semiconductor element 2 is fixed to the circuit electrode 1B by the bonding material 3 such as solder or sintered metal.

The heat dissipation base 6 and the insulating circuit substrate 1 need to efficiently release heat generated in the power semiconductor element 2. For this reason, aluminum (Al), a composite material (Al—SiC) of aluminum and silicon carbide, or the like is used for the heat dissipation base 6. Aluminum oxide (Al₂O₃), aluminum nitride (AlN), silicon nitride (Si₃N₄), or the like is used for the insulating substrate 1A of the insulating circuit substrate 1, and aluminum (Al), copper (Cu), or the like is used for the circuit electrode 1B.

A main terminal 5 is bonded to a portion of the circuit electrode 1B where the power semiconductor element 2 is not mounted, and the power semiconductor element 2 and the main terminal 5 are electrically connected via the circuit electrode 1B or the circuit electrode 1B and a metal wire 4. The main terminal 5 is a plate-like metal terminal for transmitting power to the inside and the outside of the device, and an end portion on a side not bonded to the circuit electrode 1B is connected to external equipment (not illustrated) outside the case and serves as an input/output terminal of the power semiconductor device 100A. In addition, although not illustrated, the semiconductor device 100A includes a control terminal and an auxiliary terminal.

In the semiconductor device 100A of the present invention, the main terminal 5 is a plate-shaped terminal made of a plate-shaped member, and the entire portion of the plate-shaped terminal surrounded by the first insulating material 8 is covered with the second insulating material 10 having higher hardness than the first insulating material 8. With such a configuration, it is possible to prevent partial discharge starting, when the main terminal 5 is heated, from a void occurring between the main terminal 5 and the first sealing resin 8 or a void occurring by water vapor having entered from the outside of the semiconductor device 100A through the first sealing resin 8.

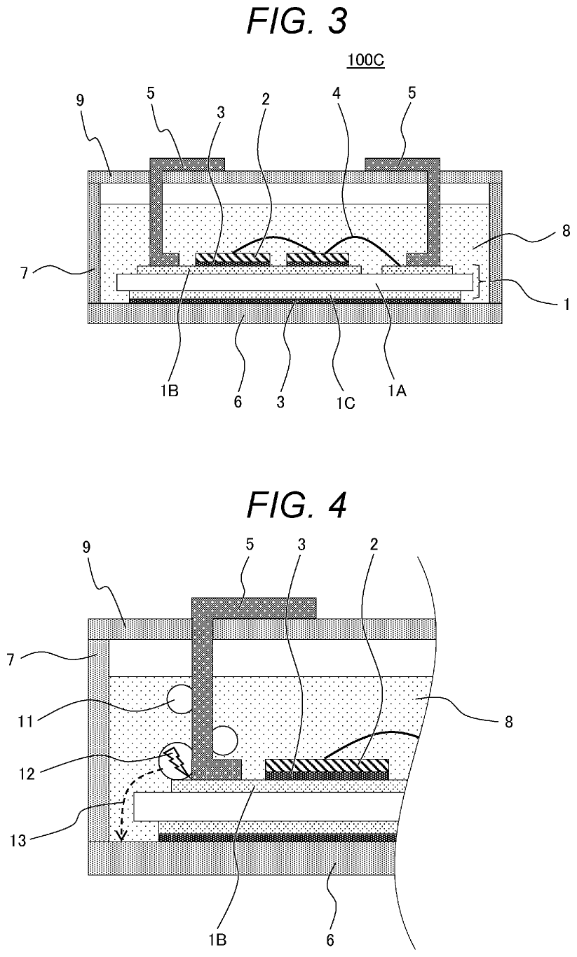

Effects of the present invention described above will be described in detail while being compared with a configuration of a conventional semiconductor device. FIG. 3 is a schematic cross-sectional view of a power semiconductor device of a first comparative example (first conventional example), and FIG. 4 is an enlarged view of a main terminal and a periphery thereof of FIG. 3. In a power semiconductor device 100C having a structure as illustrated in FIG. 3, when a current flowing through the power semiconductor element 2 is increased to cause a high-temperature operation, the main terminal 5 connected to the insulating circuit substrate 1 is also heated to increase a temperature. When viewed microscopically, unevenness is formed on the front surface of the main terminal 5. In addition, since the main terminal 5 is manufactured by cutting a metal plate such as copper, the cut surface is formed to have much unevenness than the front surface. A part of the main terminal 5 and a bonded portion between the main terminal 5 and the insulating circuit substrate 1 are sealed by the first insulating material (silicone gel) 8. However, since the silicone gel is sealed in a state of being in close contact with the main terminal 5 rather than in a state of being chemically adhered thereto, voids in which the silicone gel 8 does not exist may exist in the uneven portion of the front surface of the main terminal 5.

The silicone gel 8 is a material that repels water droplets and hardly absorbs moisture, but is a material that easily passes through water vapor. For this reason, when the power semiconductor device 100C is placed under high temperature and high humidity, the water vapor component that has passed through the silicone gel 8 reaches an interface with the main terminal 5 and accumulates thereon, and when the main terminal 5 is heated, the moisture accumulated at the interface is vaporized, and as illustrated in FIG. 4, voids 11 may occur in the silicone gel 8 around the main terminal 5. Since a voltage is applied between the main terminal 5 and the heat dissipation base 6, the relative permittivity of the silicone gel 8 is about 3.0, and the relative permittivity of the void (air) is 1.0, a high voltage is shared by the void, and when the applied voltage is high, there is a risk that partial discharge occurs in the void. In addition, when the applied voltage is high, and the partial discharge continuously occurs, there is a possibility that dielectric breakdown occurs between the main terminal 5 and the heat dissipation base 6.

In the power semiconductor device 100A of the present invention, the entire portion surrounded (sealed) by the gel-like first insulating material 8 of the main terminal 5 is covered with the second insulating material 10 having a higher hardness than the first insulating material 8. The second insulating material 10 is only required to be a resin having a higher hardness than the gel-like first insulating material 8 and is not particularly limited, but a resin that firmly adheres to the main terminal 5 is preferable. In the power semiconductor device 100A illustrated in FIG. 1, a polyamideimide resin (PAI) has been used. In addition to the PAI, an epoxy resin, a fluororesin, an acrylic resin, a silicone resin, and the like can be used. The gel-like first insulating material 8 is gel-like and soft, and therefore voids are easily formed when moisture is vaporized. Since the second insulating material 10 is a resin having a higher hardness than gel, for example, the second insulating material does not swell as a void even when moisture accumulates at the interface between the second insulating material 10 and the main terminal 5.

With the above configuration, in the power semiconductor device 100A according to the present embodiment, even when the environment in which the power semiconductor device is installed is in a high temperature and high humidity state, the entire portion of the main terminal 5 surrounded by the first insulating material 8 is covered with the second insulating material 10, and the main terminal 5 and the second insulating material 10 are adhered to each other. Therefore, water vapor that has passed through the gel-like first insulating material 8 does not pass through the second insulating material 10 and does not accumulate at the interface between the main terminal 5 and the second insulating material 10. In addition, even when voids exist between the unevenness of the front surface of the main terminal 5 and the second insulating material 10, since the second insulating material 10 is a hard material, the voids do not expand due to heating of the main terminal Thus, the formation of voids is suppressed even when the main terminal 5 is heated. Since no void is formed, no partial discharge occurs even when a high voltage is applied between the main terminal 5 and the heat dissipation base 6.

The power semiconductor device 100A having the above-described configuration is manufactured by the following procedure. The power semiconductor element 2 is, for example, a switchable element such as an IGBT or a diode, and is bonded to the circuit electrode 1B of the insulating circuit substrate 1 via the bonding material 3 such as solder or sintered metal. Then, the electrode on the other surface of the power semiconductor element 2 that is not bonded to the circuit electrode 1B of the insulating circuit substrate 1 and the circuit electrode 1B not bonded to the power semiconductor element 2 among the circuit electrodes 1B of the insulating circuit substrate 1 are connected by the metal wire 4. Next, the insulating circuit substrate 1 on which the power semiconductor element 2 is mounted is bonded to the heat dissipation base 6 via a bonding material such as solder. Thereafter, the resin case 7 is attached to the outer peripheral portion of the heat dissipation base via an adhesive or the like, and the main terminal 5 is bonded to the front surface of the circuit electrode 1B of the insulating circuit substrate 1. The second insulating material 10 is applied to the front surface of the main terminal 5 and dried. Then, finally, the gel-like first insulating material 8 (silicone gel) is injected and cured inside the resin case 7, and the resin case lid 9 is covered to complete the power semiconductor device 100A.

Herein, the configurations of the present invention will be compared with those of PTL 1 and PTL 2 described above. In PTL 1, the main terminal (terminal 14) arranged on the case side plate 11 is sealed with the second sealing resin (silicone gel) 120, and there is a possibility that a void occurs in the silicone gel as in the configuration illustrated in FIGS. 3 and 4. However, there is no description on the occurrence of this void, and no measure is taken for preventing partial discharge due to the occurrence of the void.

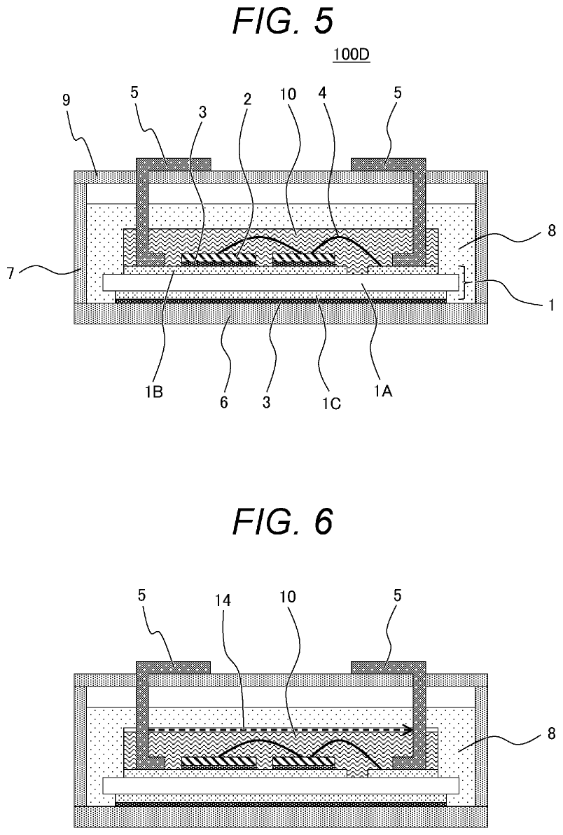

FIG. 5 is a schematic cross-sectional view of a power semiconductor device of the second comparative example (conventional second example), and FIG. 6 is a view illustrating a current leak generated between main terminals in the power semiconductor device of FIG. 5. The configuration of the power semiconductor device 100D in FIG. 5 is a configuration corresponding to PTL 2, and the bonded portion between the insulating circuit substrate 1 and the main terminal 5 and the vicinity thereof are covered with the second insulating material 10 (first sealing resin 9 in PTL 2) having a higher elastic modulus than the first insulating material 8 (second sealing resin 13 in PTL 2). A portion of the main terminal 5 not covered with the second insulating material 10 is covered with the first insulating material 8. That is, a portion of the main terminal 5 in contact with the first insulating material 8 has a portion not covered with the second insulating material 10, and the occurrence of voids on the front surface of the main terminal cannot be completely prevented.

As illustrated in FIG. 6, an interface between the first insulating material 8 and the second insulating material 10 is formed between the main terminal 5 on the left side in the drawing and the main terminal 5 on the right side in the drawing. When the interface is formed in this way, moisture accumulates in the interface, and a problem also may occur that a current leaks between the main terminal on the left side in the drawing and the main terminal 5 on the right side in the drawing (indicated by the arrow 14 in FIG. 6). On the other hand, in the present invention, the entire portion of the main terminal 5 surrounded by the first insulating material 8 is covered with the second insulating material 10, and thus even when an interface of the first insulating material 8 and the second insulating material 10 is formed between the main terminal 5 on the left side of the drawing and the main terminal 5 on the right side of the drawing as illustrated in FIG. 6 and moisture is accumulated at the interface, the main terminal 5 is covered with the second insulating material 10 at the portion where moisture is accumulated, so that it is possible to prevent leakage of a current as in FIG. 6.

### Second Embodiment

FIG. 2 is a schematic cross-sectional view illustrating a second embodiment of the power semiconductor device of the present invention. In the power semiconductor device 100B according to the present embodiment, in addition to the entire portion of the main terminal 5 surrounded by the first insulating material 8, the bonded portion between the power semiconductor element 2 and the circuit electrode 1B of the insulating circuit substrate 1 is covered with the second insulating material 10 having a higher hardness than the first insulating material 8.

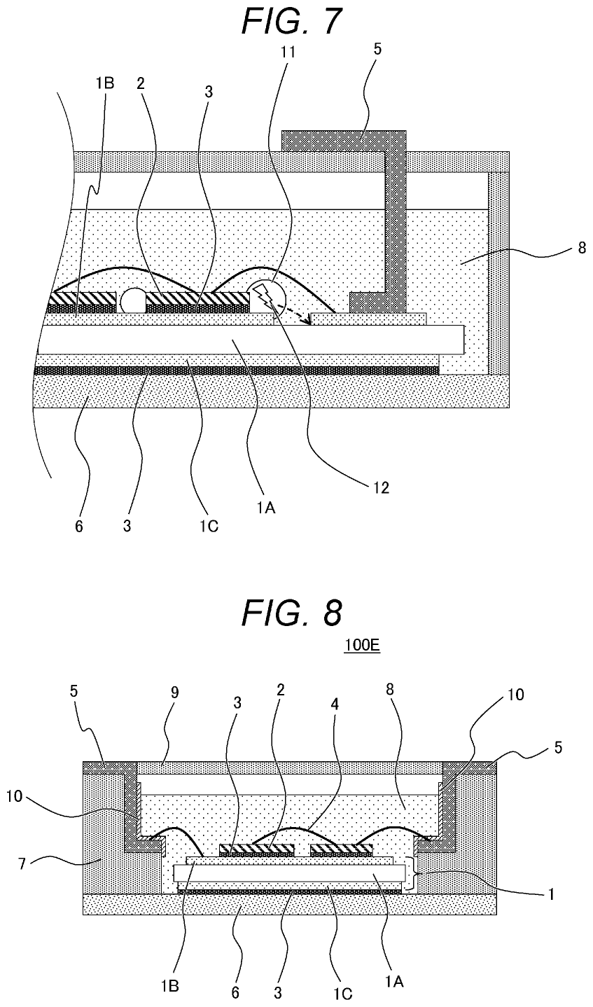

FIG. 7 is a schematic cross-sectional view in a case where a sintered metal such as copper or silver is used for the bonding material 3 between the power semiconductor element 2 and the circuit electrode 1B of the insulating circuit substrate. The sintered metal is a sintered body that is solidified by heating a metal powder at a temperature lower than a melting point, and is porous. Therefore, when the sintered metal is used for the bonding material 3, moisture may accumulate between the first insulating material 8 and the bonding material 3, and the voids 11 may be occur around the bonding material 3.

Therefore, in the power semiconductor device 100B according to the second embodiment of the present invention, as illustrated in FIG. 2, in addition to the entire portion of the main terminal 5 surrounded by the first insulating material 8, the bonded portion between the power semiconductor element 2 and the circuit electrode 1B of the insulating circuit substrate 1 is covered with the second insulating material 10 having a higher hardness than the first insulating material 8. With such a configuration, in the power semiconductor device 100B of the present embodiment, even when the environment in which the power semiconductor device is installed is in a high temperature and high humidity state, the bonded portion between the main terminal and the circuit electrode 1B of the insulating circuit substrate 1 and the bonded portion between the power semiconductor element 2 and the circuit electrode 1B of the insulating circuit substrate 1 are covered with the second insulating material 10 and adhered. Therefore, the water vapor that has passed through the first insulating material 8 does not pass through the second insulating material 10, and does not accumulate at the interface between the main terminal 5 and the second insulating material 10, the interface between the second insulating material 10 and the bonded portion between the main terminal 5 and the circuit electrode 1B of the insulating circuit substrate 1, and the interface between the second insulating material 10 and the bonded portion between the power semiconductor element 2 and the circuit electrode 1B of the insulating circuit substrate 1. Thus, even when the main terminal 5 and the power semiconductor element 2 are heated, the formation of the void 11 as illustrated in FIG. 7 is suppressed. Since no void 11 is formed, no partial discharge 12 occurs even when a high voltage is applied between the main terminal 5 and the heat dissipation base 6, between the electrodes of the power semiconductor element 2, or between the circuit electrode 1B and another circuit electrode 1B.

### Third Embodiment

FIG. 8 is a schematic cross-sectional view illustrating a third embodiment of the power semiconductor device of the present invention. FIG. 8 corresponds to a modification in which the position of the main terminal 5 in FIG. 1 is changed. A power semiconductor device 100E illustrated in FIG. 8 includes the resin case 7 that houses the insulating circuit substrate 1, the power semiconductor element 2, and the first insulating material 8. The main terminal 5 is provided on the resin case 7, and is electrically connected to the circuit electrode 1B on the front surface of the insulating substrate 1A or the electrode of the power semiconductor element 2 via the metal wire 4. Then, the entire portion of the main terminal 5 surrounded by the first insulating material 8 is covered with the second insulating material 10 having a higher hardness than the first insulating material 8. As described above, even when the main terminal 5 that is a plate-shaped terminal is provided in resin case 7, the effect of the present invention can be obtained by covering the entire portion of the main terminal 5 surrounded by the first insulating material 8 with the second insulating material 10 having a higher hardness than the first insulating material 8.

Although not illustrated, as in the second embodiment described above, the bonded portion between the power semiconductor element 2 and the circuit electrode 1B of the insulating circuit substrate 1 may be covered with the second insulating material 10 having a higher hardness than the first insulating material 8. Even with such a configuration, the effect of the present invention can be obtained.

### Examples

### [Production, Test, and Evaluation of Power Semiconductor Device]

Next, a sample of the power semiconductor device according to the embodiment of the present invention was manufactured and evaluated.

Hereinafter, in order to verify the effect on the insulation reliability of the power semiconductor device according to the present invention, results will be described obtained when the power semiconductor devices 100A and 100B described in the first and second embodiments, respectively, and the power semiconductor devices 100C and 100D described in the first and second comparative examples, respectively, were manufactured, the power semiconductor devices were heated on a hot plate after a humidification treatment at a high temperature and a high humidity, and a void occurrence state observation, a partial discharge test, and measurement of an insulation resistance between terminals were performed.

Note that as described above, an object of the present invention is to prevent the occurrence of voids in the first insulating material 8 around the main terminal 5 and the occurrence of partial discharge when the power semiconductor device in which the main terminal 5 is sealed with the gel-like first insulating material 8 is installed in a high temperature and high humidity environment. Therefore, in this test, the case lid was not attached to each of the power semiconductor devices 100A, 100B, 100C, and 100D, so that water vapor easily passed through the first insulating material 8, and the void occurrence state inside the power semiconductor device could be observed.

In this test, each sample corresponding to each of the power semiconductor devices 100A, 100B, 100C, and 100D was placed in a high temperature and high humidity tank under a temperature and humidity condition of 85° C. and 85% R.H. (relative humidity), and a humidification treatment was performed for 1000 hours. After the humidification treatment for 1000 hours, each sample was taken out from the high temperature and high humidity tank, and first, the insulation resistance between two main terminals 5 was measured. Using an insulation resistance meter, 500 V was applied between the terminals, and a one-minute value of the insulation resistance between the main terminals was measured.

After the insulation resistance measurement, the sample was immediately placed on a hot plate and heated at 120° C. for 15 minutes. The voids occurring from the periphery of the bonding material 3 between the main terminal 5 of the sample and the power semiconductor element 2 and the circuit electrode 1B of the insulating circuit substrate 1 were visually observed while being heated.

Then, immediately after heating, a voltage (partial discharge starting voltage) at which partial discharge occurred in each sample when the main terminal 5, the control terminal, and the auxiliary terminal were all short-circuited, and an AC voltage was applied between all the terminals and the heat dissipation base to gradually increase the AC voltage from 0 V was measured using a partial discharge measuring device. Herein, a threshold for determining that partial discharge has occurred was set to 10 pC. Note that the test voltage of the partial discharge was set to a maximum of 7 kVrms (effective value).

Table 1 summarizes the void occurrence state observation, the partial discharge test, and the insulation resistance measurement result of each power semiconductor device according to the embodiment and the comparative example of the present invention. As shown in Table 1, in the sample (first example) corresponding to the power semiconductor device 100A of the first embodiment and the sample (second example) corresponding to the power semiconductor device 100B of the second embodiment, it was confirmed that voids did not occur in the first insulating material 8 around the main terminal 5 and around the power semiconductor element 2. On the other hand, in the sample (first comparative example) corresponding to the power semiconductor device 100C of the first comparative example and the sample (second comparative example) corresponding to the power semiconductor device 100D of the second comparative example, voids occurred in the first insulating material 8 around the main terminal 5.

In the partial discharge test, in the first example, the second example, and the second comparative example, there was no occurrence of partial discharge at the test voltage maximum of 7 kVrms. On the other hand, in the first comparative example, partial discharge occurred at 5.6 kVrms. This is considered to be a partial discharge starting from the void occurring around the main terminal 5.

In the measurement of the insulation resistance between the main terminals 5, in each of the first example, the second example, and the first comparative example, the insulation resistance showed a high resistance value of 10¹⁰Ω or more. On the other hand, in the second comparative example, the resistance value was as low as 4.6×10³Ω. This is considered to be due to the occurrence of leakage at the interface of the first insulating material 8 and the second insulating material 10 between the main terminals 5.

TABLE 1

| | | | First | Second |
|---|---|---|---|---|
| | First | Second | comparative | comparative |
| | example | example | example | example |
| Presence or absence of voids | No | No | Occurrence | Occurrence |
| around main terminal | occurrence | occurrence | | |
| Presence or absence of voids | No | No | No | No |
| around element | occurrence | occurrence | occurrence | occurrence |
| Partial discharge starting | No | No | 5.6 | No |
| voltage (kVrms) | discharge | discharge | | discharge |
| Insulation resistance between | >10¹⁰ | >10¹⁰ | >10¹⁰ | 4.6 × 10³ |
| main terminals (Ω) | | | | |

Moisture absorption treatment condition: 85° C. 85% R.H. 1000 hours
Heating condition after moisture absorption: 120° C. 15 min on hot plate

According to the embodiment of the present invention described above, the following operational effects are exhibited. In the power semiconductor devices 100A and 100B, the entire portion of the main terminal 5 surrounded by the gel-like first insulating material 8 is covered with the second insulating material 10 having a higher hardness than the first insulating material 8. In this way, the moisture accumulating at the interface between the main terminal 5 and the first insulating material 8 can be suppressed, the occurrence of voids can be suppressed, and furthermore, the occurrence of partial discharge can be suppressed, so that it is possible to provide the power semiconductor devices 100A and 100B which are compact and excellent in reliability.

Hereinbefore, as described above, according to the present invention, it has been shown that a compact and highly reliable power semiconductor device can be provided which prevents partial discharge starting, when the main terminal is heated, from the void occurring between the main terminal and the sealing resin or the void occurring by water vapor having entered from the outside of the semiconductor device through the sealing resin.

The embodiments and various modifications described above are merely examples, and the present invention is not limited to these contents unless the characteristics of the invention are impaired.

### REFERENCE SIGNS LIST

1 insulating circuit substrate
1A insulating substrate
1B circuit electrode
1C back surface electrode
2 power semiconductor element
3 bonding material
4 metal wire
5 main terminal
6 heat dissipation base
7 resin case
8 first insulating material
9 resin case lid
10 second insulating material
11 void (bubble)
12 partial discharge
13 dielectric breakdown
14 current leakage
100A, 100B, 100C, 100D, 100E power semiconductor device

1. A power semiconductor device which includes an insulating substrate, a semiconductor element provided on a front surface of the insulating substrate, and a gel-like first insulating material that seals the semiconductor element, the device comprising a plate-shaped terminal for electrically connecting the semiconductor element and external equipment, wherein an entire portion of the plate-shaped terminal surrounded by the first insulating material is covered with a second insulating material having a higher hardness than the first insulating material.

2. The power semiconductor device according to claim 1, wherein one end of the plate-shaped terminal is bonded to an electrode of the front surface of the insulating substrate.

3. The power semiconductor device according to claim 1, further comprising a case that houses the insulating substrate, the semiconductor element, and the first insulating material, wherein the plate-shaped terminal is provided in the case, and is electrically connected via a metal wire to an electrode of the front surface of the insulating substrate or an electrode of the semiconductor element.

4. The power semiconductor device according to claim 1, wherein a bonded portion between the semiconductor element and an electrode of the insulating substrate is covered with the second insulating material.

5. The power semiconductor device according to claim 4, wherein the semiconductor element and the electrode of the insulating substrate are bonded by a sintered metal.

6. The power semiconductor device according to claim 1, wherein the second insulating material is at least one of a polyamideimide resin, an epoxy resin, a fluororesin, an acrylic resin, and a silicone resin.

7. The power semiconductor device according to claim 1, wherein the second insulating material is a resin, and is in contact with the first insulating material.

8. The power semiconductor device according to claim 7, wherein the second insulating material is at least one of a polyamideimide resin, an epoxy resin, a fluororesin, an acrylic resin, and a silicone resin.
